(19) United States
(12) Patent Application Publication
(10) Pub. No.: US 2024/0425535 A1
(43) Pub. Date: Dec. 26, 2024

(54) PHOSPHORYL DERIVATIVE, USE, ORGANIC LIGHT-EMITTING DIODE, AND DISPLAY APPARATUS

(71) Applicant: BOE Technology Group Co., Ltd., Beijing (CN)

(72) Inventors: Lei CHEN, Beijing (CN); Xueqin CHEN, Beijing (CN); Bingyan LIANG, Beijing (CN); Dongxu ZHANG, Beijing (CN)

(21) Appl. No.: 18/703,729

(22) PCT Filed: May 18, 2023
(86) PCT No.: PCT/CN2023/094987

§ 371 Date: Apr. 23, 2024

(30) Foreign Application Priority Data
Jun. 15, 2022 (CN) 202210679613.7

(51) Int. Cl. C07F 9/46; C07F 7/08; H10K 85/40; H10K 85/60

(52) U.S. Cl. CPC C07F 9/46; C07F 7/081; H10K 85/40; H10K 85/60

(57) ABSTRACT

A phosphoryl derivative, the use, an organic light-emitting diode, and a display apparatus. A phosphoryl group of the phosphoryl derivative is directly bonded to two substituted or unsubstituted aryl groups, and at least is directly bonded to or is indirectly bonded via a bridge group to a non-conjugated substituent group.

### CROSS-REFERENCE TO RELATED APPLICATIONS

The present application is a U.S. National Phase Entry of International Application No. PCT/CN2023/094987, having an international filing date of May 18, 2023, which claims priority to Chinese Patent Application No. 202210679613.7 filed to the CNIPA on Jun. 15, 2022 and entitled “Phosphoryl Derivative, Use, Organic Light-Emitting Diode, and Display Apparatus”. The entire contents of the above-identified applications are hereby incorporated into the present application by reference.

### TECHNICAL FIELD

Embodiments of the present application relate to, but are not limited to, the technical field of organic electroluminescent materials, and in particular to a phosphoryl derivative, a use, an organic electroluminescent device, and a display apparatus.

### BACKGROUND

In an organic electroluminescent device (an organic light-emitting diode, OLED), an optical coupling output layer (Coupling Layer, CPL) is formed by combining a high refractive index material with a low refractive index material based on the microcavity effect, which can improve the total reflection at an interface and increase the microcavity effect of light, thus improving the optical coupling efficiency of the whole organic electroluminescent device.

An inorganic low refractive index material such as lithium fluoride (LiF) is generally used as the low refractive index material in the optical coupling output layer, but the inorganic low refractive index material generally has high water absorption, which leads to unstable performances of the organic electroluminescent device.

### SUMMARY

The following is a summary of subject matters described herein in detail. This summary is not intended to limit the protection scope of claims.

Embodiments of the present disclosure provide a phosphoryl derivative, a use, an organic electroluminescent device, and a display apparatus.

Embodiments of the present disclosure provide a phosphoryl derivative, a phosphoryl group of the phosphoryl derivative is directly linked to two substituted or unsubstituted aryls, and is at least directly linked to a non-conjugated substituent or indirectly linked to the non-conjugated substituent via a bridged group.

The non-conjugated substituent is independently selected from substituted or unsubstituted C3-C10 alkyl, substituted or unsubstituted C3-C10 cycloalkyl, or substituted or unsubstituted adamantyl.

The bridged group is independently selected from substituted or unsubstituted C6-C60 aryl, substituted or unsubstituted C10-C60 fused aryl, or substituted or unsubstituted C5-C60 5-membered or 6-membered arylheterocyclyl.

In some embodiments, the phosphoryl derivative includes two phosphoryl groups, and the two phosphoryl groups are indirectly linked.

In some embodiments, the two phosphoryl groups are indirectly linked by a substituted or unsubstituted aryl directly linked to the phosphoryl group or by the non-conjugated substituent.

In some embodiments, the bridged group is a substituted or unsubstituted aryl.

In some embodiments, any one or more of the substituted aryl directly linked to the phosphoryl group, the non-conjugated substituent and the bridged group is further linked to a sterically hindered substituent independently selected from halogen-substituted alkane, nitro, nitrile group, substituted or unsubstituted C1-C30 alkyl, silyl, substituted or unsubstituted C2-C30 alkenyl, substituted or unsubstituted C1-C30 alkoxy, substituted or unsubstituted C1-C30 thioether group, substituted or unsubstituted C6-C50 aryl, or C2-C50 heteroaryl formed from a substituted or unsubstituted C2-C9 ring structure.

In some embodiments, the phosphoryl derivative has a structure represented by general formula (I) or general formula (II):

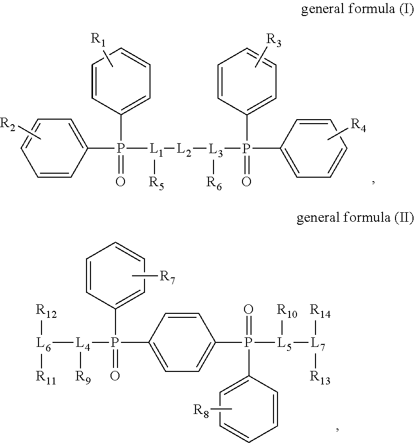

in the general formula (I), L1, L2, and L3 are each independently selected from C6-C60 aryl, C10-C60 fused aryl, C5-C60 5-membered or 6-membered arylheterocyclyl, or the non-conjugated substituent, and at least one of L1, L2, and L3 is the non-conjugated substituent; R1, R2, R3, R4, R5, and R6 are each independently selected from hydrogen, deuterium, halogen, halogen-substituted alkane, nitro, nitrile group, substituted or unsubstituted C1-C30 alkyl, silyl, substituted or unsubstituted C2-C30 alkenyl, substituted or unsubstituted C1-C30 alkoxy, substituted or unsubstituted C1-C30 thioether group, substituted or unsubstituted C6-C50 aryl, or C2-C50 heteroaryl formed from a substituted or unsubstituted C2-C9 ring structure;

in the general formula (II), L4, L5, L6, and L7 are each independently selected from C6-C60 aryl, C10-C60 fused aryl, C5-C60 5-membered or 6-membered arylheterocyclyl, the non-conjugated substituent, and at least one of L4, L5, L6, and L7 is the non-conjugated substituent; R7, R8, R9, R10, R11, R12, R13, and R14 are each independently selected from hydrogen, deuterium, halogen, halogen-substituted alkane, nitro, nitrile group, substituted or unsubstituted C1-C30 alkyl, silyl, substituted or unsubstituted C2-C30 alkenyl, substituted or unsubstituted C1-C30 alkoxy, substituted or unsubstituted C1-C30 thioether group, substituted or unsubstituted C6-C50 aryl, or C2-C50 heteroaryl formed from a substituted or unsubstituted C2-C9 ring structure.

In some embodiments, the phosphoryl derivative has a structure represented by any one of the following formulas:

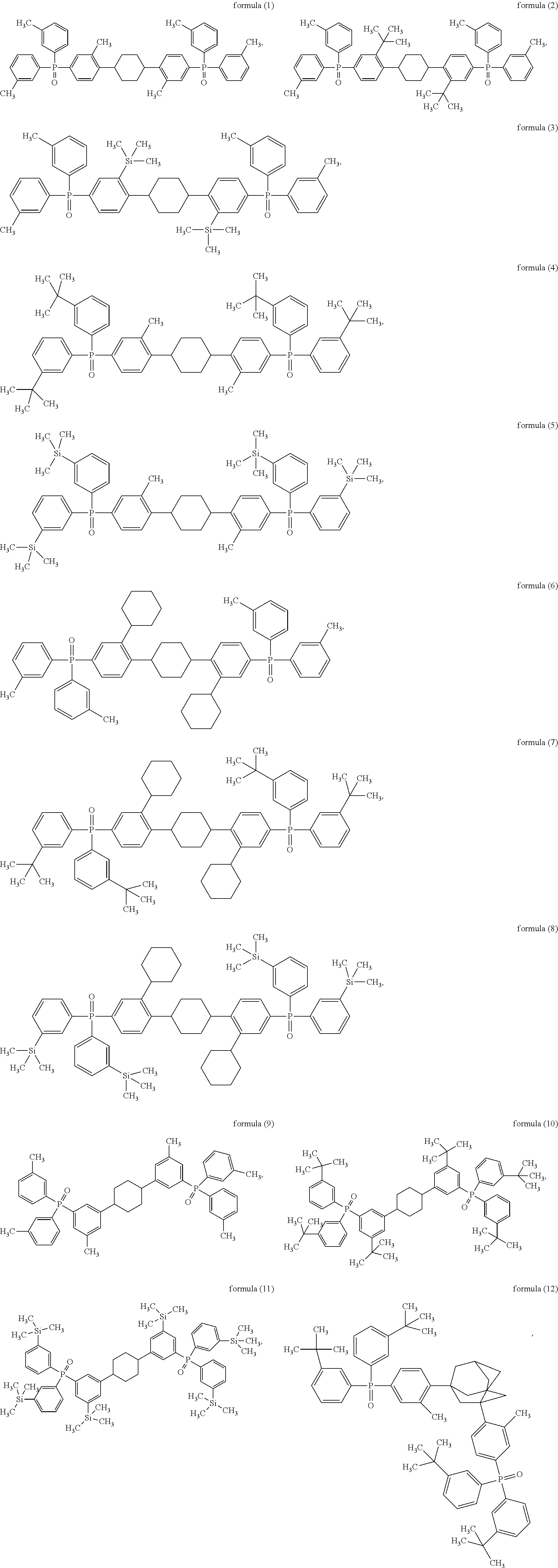

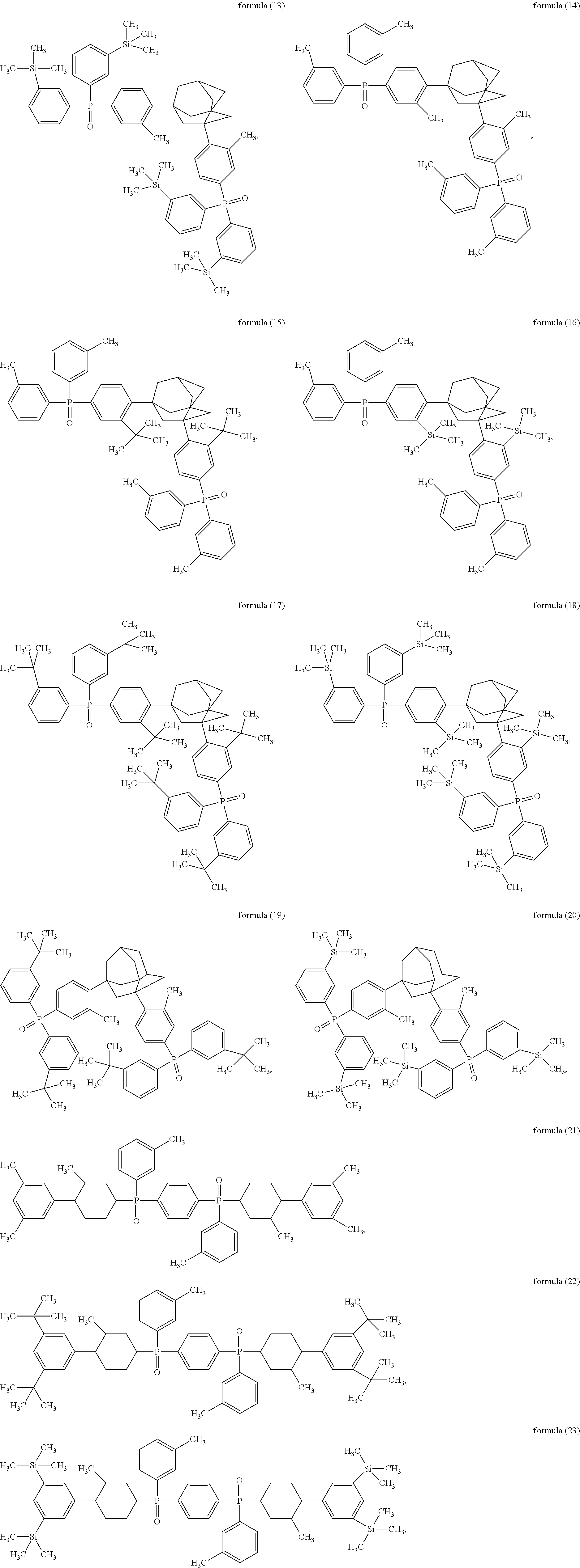

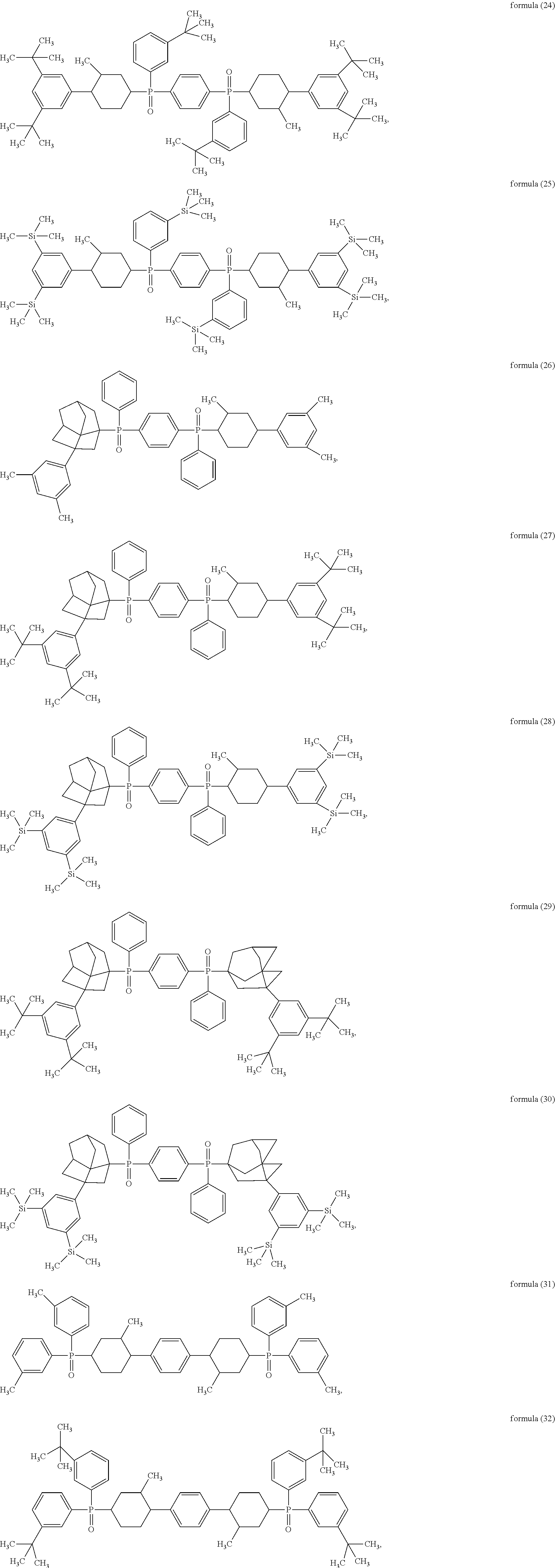

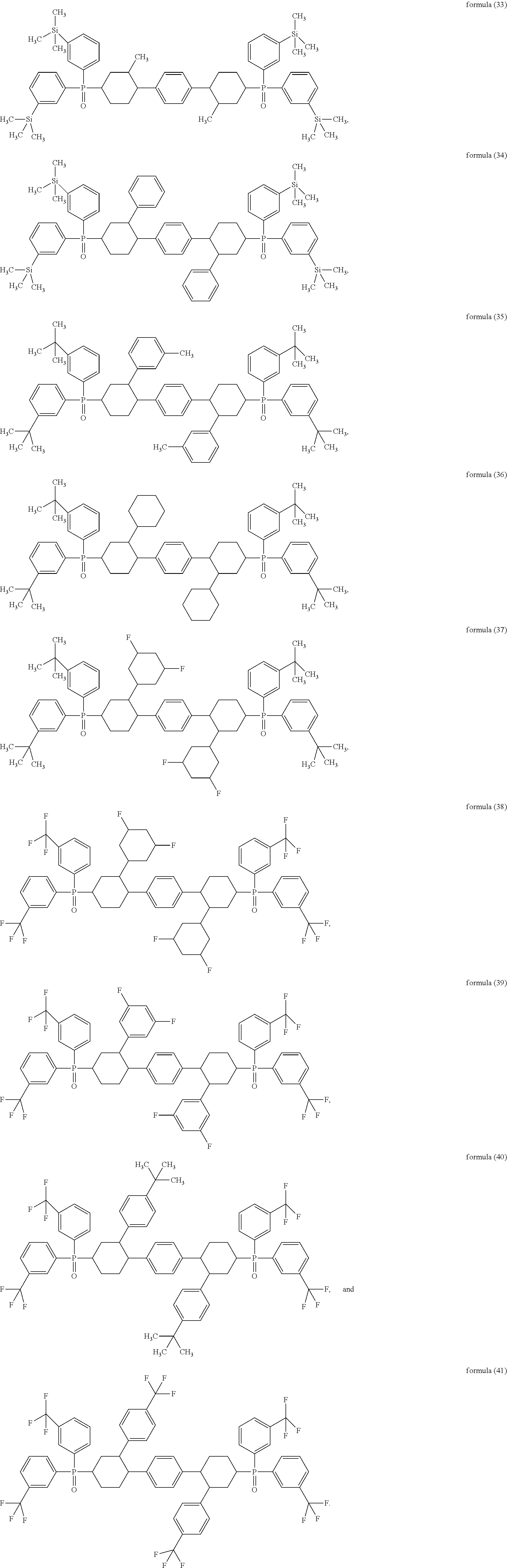

The embodiments of the present disclosure further provide use of the above phosphoryl derivative, and the phosphoryl derivative is used for preparing an optical coupling output layer of an organic electroluminescent device.

The embodiments of the present disclosure further provide an organic electroluminescent device including an anode electrode layer, a hole injection layer, a hole transport layer, a light emitting layer, an electron transport layer, an electron injection layer, a cathode electrode layer, and an optical coupling output layer which are sequentially laminated, wherein the optical coupling output layer includes the above phosphoryl derivatives.

The embodiments of the present disclosure further provide a display apparatus, including the above organic electroluminescent device.

Other aspects of the present disclosure may be comprehended after the drawings and the detailed descriptions are read and understood.

### BRIEF DESCRIPTION OF DRAWINGS

In order to describe technical solutions in embodiments of the present disclosure more clearly, the drawings to be used in the embodiments of the present invention will be introduced below in brief. The drawings described below are only some of the embodiments of the present disclosure, and one skilled in the art may obtain other drawings according to these drawings without paying any inventive effort.

FIG. 1 shows a structural schematic diagram of an organic electroluminescent device in an embodiment of the present disclosure.

FIG. 2 shows a structural schematic diagram of an organic electroluminescent device according to another embodiment of the present disclosure.

### DETAILED DESCRIPTION

Technical solutions in embodiments of present disclosure will be described clearly and completely with reference to the drawings in the embodiments of present disclosure. The described embodiments are apparently only part of the embodiments of the present disclosure, rather than all of the embodiments. Based on the embodiments of the present disclosure, all other embodiments obtained by a person skilled in the art without paying any inventive effort are within the scope of protection of the present application.

In addition, in the present disclosure, reference numbers and/or reference letters may be repeated in different embodiments. Such repetition is for a purpose of simplification and clarity, and it does not indicate a relationship between various embodiments and/or arrangements discussed. Further, the embodiments of the present disclosure provide examples of various specific processes and materials, but a person skilled in the art may be aware of the application of other processes and/or the use of other materials.

The embodiments of the present disclosure will be described below with reference to the drawings in detail.

The first major aspect of the embodiments of the present disclosure provides a phosphoryl derivative as represented by general formula (I) and general formula (II), a phosphoryl group of the phosphoryl derivative is directly linked to two substituted or unsubstituted aryls, and is at least directly linked to a non-conjugated substituent or indirectly linked to the non-conjugated substituent via a bridged group.

The non-conjugated substituent is independently selected from substituted or unsubstituted C3-C10 alkyl, substituted or unsubstituted C3-C10 cycloalkyl, or substituted or unsubstituted adamantyl.

The bridged group is independently selected from substituted or unsubstituted C6-C60 aryl, substituted or unsubstituted C10-C60 fused aryl, or substituted or unsubstituted C5-C60 5-membered or 6-membered arylheterocyclyl.

The above phosphoryl derivatives as organic low refractive index materials are used in an optical coupling output layer instead of the combination of the inorganic low refractive index materials and high refractive index materials. The phosphoryl group is directly or indirectly linked to the non-conjugated substituent in the phosphoryl derivatives, and by a molecular structure of the non-conjugated substituent combined with the phosphoryl group, the overall conjugation of the molecule and the delocalization of the electron cloud are reduced, the spatial volume of the molecule is increased, thereby reducing the refractive index of the material, and the refractive index of the phosphoryl derivative meets the refractive index requirement of the optical coupling output layer for the low refractive index materials. At the same time, the organic low refractive index material phosphoryl derivative has lower water absorption than that of the inorganic low refractive index material, and can avoid the problem of unstable performance of the organic electroluminescent device caused by the inorganic low refractive index materials having high water absorption; further, the organic low refractive index material phosphoryl derivative has better stress resistance than that of the inorganic low refractive index material, and can avoid the fragile defect of a flexible display apparatus caused by the poor stress resistance when used in the flexible display apparatus.

As new type of display devices, OLEDs have been paid more and more attention. Due to characteristics such as active luminescence, high luminous brightness, high resolution, wide viewing angle, fast response speed, low energy consumption and flexibility, OLEDs have become hot mainstream display products in the market. With the continuous development of products, customers have higher and higher resolution and lower power consumption requirements, and there is a need to develop devices with high efficiency, low voltage and long life. The optimization and performance improvement of OLEDs can improve the combination of any one of functional layers and different functional layer materials, and at the same time, can increase the microcavity effect of the whole device to improve the optical coupling efficiency and further improve the efficiency of the device.

In order to increase the microcavity effect in flexible display encapsulation, high refractive index and low refractive index materials are combined to form an optical coupling output layer to change the optical path and propagation direction, which is similar to the formation of diffuse reflection phenomenon, and breaks through the optical limitation of color polarization caused by the microcavity effect, to further improve the total reflection of light emitted at an interface and increase the microcavity effect of the light, thereby improving the optical coupling efficiency of the whole device. As for the optical coupling output layer, materials are focused on the high refractive index materials, and the low refractive index materials mainly use inorganic materials, such as LiF.

It can be found in the embodiments of the present disclosure by the research that because the inorganic low refractive index material in the optical coupling output layer has higher water absorption, performances of the organic electroluminescent devices are unstable, which affects the service life of the organic electroluminescent devices. At the same time, the inorganic low refractive index materials also have the defect of poor stress resistance, which is one of the factors that lead to fragile flexible display apparatus when the organic electroluminescent devices containing inorganic low refractive index materials optical coupling output layers are applied to the flexible display apparatus.

Based on the above research, the embodiments of the present disclosure provide a phosphoryl derivative, which reduces the overall conjugation of the formed phosphoryl derivative and increases the spatial volume of the molecule by the molecular structure of the phosphoryl group combined with the non-conjugated substituent in the phosphoryl group derivative, thereby reducing the refractive index of the phosphoryl derivative material and making it possible for the phosphoryl derivative to be applied to the optical coupling output layer in the electroluminescent device. Moreover, the phosphoryl derivative belongs to the organic low refractive index material, has lower water absorption and higher stress resistance, overcomes the defects of the inorganic low refractive index material in the organic electroluminescent device, which can not only improve the performance stability, life, stress resistance and light emission efficiency of the organic electroluminescent device, but also can make the method for the preparation of the phosphoryl derivatives simple, improve the production efficiency, and reduce the production cost, compared with defects easily caused by the inorganic low refractive index materials, such as film peeling and evaporation cavity crystallization.

As an alternative embodiment, as represented by general formula (I) and general formula (II), in the phosphoryl derivatives, the phosphoryl derivative comprises two phosphoryl groups, and the two phosphoryl groups are indirectly linked.

As a further alternative embodiment, as represented by general formula (I) and general formula (II), the two phosphoryl groups are indirectly linked by a substituted or unsubstituted aryl directly linked to the phosphoryl group, or by the non-conjugated substituent. As represented by formula (21), formula (22), formula (23), formula (24), formula (25), formula (26), formula (27), formula (28), formula (29) and formula (30), the two phosphoryl groups are indirectly linked via a substituted or unsubstituted aryl directly linked to the phosphoryl group; as represented by formula (1), formula (2), formula (3), formula (4), formula (5), formula (6), formula (7), formula (8), formula (9), formula (10), formula (11), formula (12), formula (13), formula (14), formula (15), formula (16), formula (17), formula (18), formula (19), formula (20), formula (31), formula (32), formula (33), formula (34), formula (35), formula (36), formula (37), formula (38), formula (39), formula (40) and formula (41), the two phosphoryl groups are indirectly linked via the non-conjugated substituent, and the number of the non-conjugated substituent between the two phosphoryl groups may be one or two, and the two non-conjugated substituents are indirectly linked by the bridged group.

As an alternative embodiment, the bridged group is a substituted or unsubstituted aryl in the phosphoryl derivative. That is, in this embodiment, as represented by formula (1), formula (2), formula (3), formula (4), formula (5), formula (6), formula (7), formula (8), formula (9), formula (10), formula (11), formula (12), formula (13), formula (14), formula (15), formula (16), formula (17), formula (18), formula (19) and formula (20), the phosphoryl group is directly linked to three substituted or unsubstituted aryls, and indirectly linked to the non-conjugated substituent via one of the substituted or unsubstituted aryls. The three substituted or unsubstituted aryls directly linked to the phosphoryl group have mutual existence angles, and the three substituted or unsubstituted aryls and phosphoryl group fragment form a spatial three-dimensional hook type, which can further destroy the conjugation of the molecule and reduce the polarizability of the molecule; at the same time, the molecular volume further increases. Both the decrease in molecular polarizability and the increase in molecular volume are beneficial to the decrease in the refractive index of the phosphoryl derivative material.

As an alternative embodiment, in the phosphoryl derivatives, any one or more of a substituted aryl directly linked to the phosphoryl group, the non-conjugated substituent and the bridged group is further linked to a sterically hindered substituent independently selected from halogen-substituted alkane, nitro, nitrile group, substituted or unsubstituted C1-C30 alkyl, silyl, substituted or unsubstituted C2-C30 alkenyl, substituted or unsubstituted C1-C30 alkoxy, substituted or unsubstituted C1-C30 thioether group, substituted or unsubstituted C6-C50 aryl, or C2-C50 heteroaryl formed from a substituted or unsubstituted C2-C9 ring structure. In this embodiment, as represented by formulas (1) to (41), any one or more of the substituted aryl directly linked to the phosphoryl group, the non-conjugated substituent and the bridged group is further linked to a sterically hindered substituent with larger steric hindrance. By adding the sterically hindered substituent, the spatial torsion of adjacent groups can be enlarged and the molecular volume can be enlarged, thereby facilitating further decrease in the refractive index of the phosphoryl derivative materials.

A second major aspect of the embodiments of the present disclosure further provides a use of the above phosphoryl derivatives for preparing an optical coupling output layer of an organic electroluminescent device.

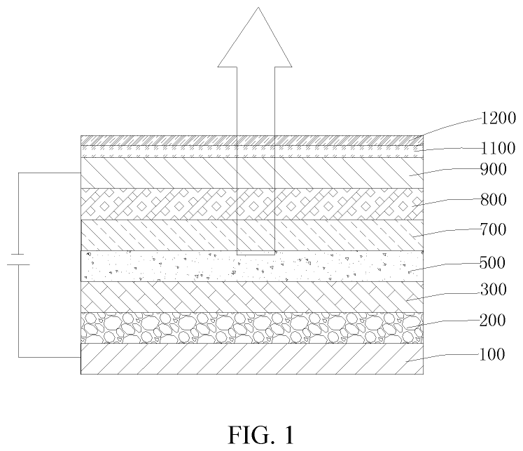

A third major aspect of the embodiments of the present disclosure further provides an organic electroluminescent device. As shown in FIG. 1, the organic electroluminescent device includes an anode electrode layer (Anode) 100, a hole injection layer (HIL) 200, a hole transport layer (HTL) 300, a light emitting layer (EML, Emission layer) 500, an electron transport layer (ETL) 700, an electron injection layer (EIL) 800, a cathode electrode layer (Cathode) 900, and an optical coupling output layer (CPL, Capping Layer) containing the above phosphoryl derivatives, which are sequentially laminated. In an exemplary embodiment, a first optical coupling output layer 1100 and a second optical coupling output layer 1200 may be further provided on a surface at a side of the cathode electrode layer 900 away from the anode electrode layer 100.

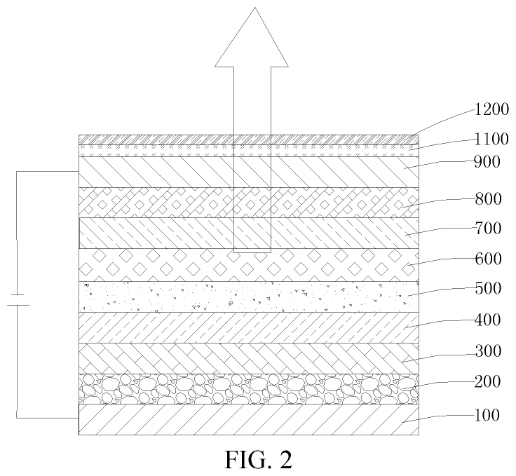

Further alternatively, as shown in FIG. 2, the organic electroluminescent device includes an anode electrode layer (Anode) 100, a hole injection layer (HIL) 200, a hole transport layer (HTL) 300, an electron barrier layer (EBL, Electron Block Layer) 400, a light emitting layer (EML, Emission layer) 500, a hole barrier layer (HBL, Hole Block Layer) 600, an electron transport layer (ETL) 700, an electron injection layer (EIL) 800, and a cathode electrode layer (Cathode) 900, and an optical coupling output layer (CPL, Capping Layer) containing the above phosphoryl derivatives, which are sequentially laminated. In an exemplary embodiment, a first optical coupling output layer 1100 and a second optical coupling output layer 1200 may be further provided on a surface at a side of the cathode electrode layer 900 away from the anode electrode layer 100.

Herein, materials for the hole injection layer may be selected from an inorganic oxide, such as a molybdenum oxide, a titanium oxide, a vanadium oxide, a rhenium oxide, a ruthenium oxide, a chromium oxide, a zirconium oxide, a hafnium oxide, a tantalum oxide, a silver oxide, a tungsten oxide, or a manganese oxide; or may also be selected from a p-type dopant of a strong electron-withdrawing system and a dopant of a hole transport material, such as hexacyanohexaazatriphenylene, 2,3,5,6-tetrafluoro-7,7,8,8-tetracyano-p-quinone dimethane (F4TCNQ), or 1,2,3-tri [(cyano) (4-cyano-2,3,5,6-tetrafluorophenyl)methylene]cyclopropane.

Materials for the hole transport layer/electron barrier layer may be selected from aromatic amines having hole transport properties, and dimethylfluorene, or carbazole materials, such as 4,4′-bis [N-(1-naphthyl)-N-phenylamino]biphenyl (NPB), N,N′-bis(3-methylphenyl)-N,N′-diphenyl-[1,1′-biphenyl]-4,4′-diamine (TPD), 4-phenyl-4′-(9-phenylfluorene-9-yl)triphenylamine (BAFLP), 4,4′-bis [N-(9,9-dimethylfluorene-2-yl)-N-phenylamino]biphenyl(DFLDPBi), 4,4′-di(9-carbazolyl) biphenyl (CBP), or 9-phenyl-3-[4-(10-phenyl-9-anthryl)phenyl]-9H-carbazole (PCzPA).

Blue light emitting materials in the light emitting layer may be selected from pyrene derivatives, anthracene derivatives, fluorene derivatives, perylene derivatives, styrylamine derivatives, metal complexes, N1,N6-di([1,1′-biphenyl]-2-yl)-N1,N6-di([1,1′-biphenyl]-4-yl) pyrene-1,6-diamine, 9,10-di-(2-naphthyl) anthracene (ADN), 2-methyl-9,10-di-2-naphthyl anthracene (MADN), 2,5,8,11-tetratert-butyl perylene (TBPe), 4,4′-di [4-(diphenylamino) styryl]biphenyl (BDAVBi), 4,4′-di [4-(di-p-tolylamino) styryl]biphenyl (DPAVBi), or di(4,6-difluorophenylpyridine-C2,N)pyridine formyl iridium (FIrpic).

Materials for the hole barrier layer/electron transport layer may generally be aromatic heterocyclic compounds, for example, imidazole derivatives such as a benzimidazole derivative, an imidazopyridine derivative, and a benzimidazophenanthridine derivative; an azine derivative such as a pyrimidine derivative and a triazine derivative; a compound including a nitrogen-containing six-membered ring structure (also including a compound having a substituent of a phosphine oxide system on a heterocyclic ring) such as a quinoline derivative, an isoquinoline derivative, and a phenanthroline derivative; such as 2-(4-biphenyl)-5-(4-tert-butylphenyl)-1,3,4-oxadiazole (PBD), 1,3-bis [5-(4-tert-butylphenyl)-1,3,4-oxadiazole-2-yl]benzene (OXD-7), 3-(4-tert-butylphenyl)-4-phenyl-5-(4-biphenyl)-1,2,4-triazole (TAZ), 3-(4-tert-butylphenyl)-4-(4-ethylphenyl)-5-(4-biphenyl)-1,2,4-triazole (p-EtTAZ), bathophenanthroline (BPhen), (BCP), or 4,4′-bis(5-methylbenzoxazole-2-yl) stilbene (BzOs).

The electron injection layer is usually an alkali metal or a metal, such as LiF, Yb, Mg, Ca or compounds thereof.

A fourth major aspect of the embodiments of the present disclosure further provides a display apparatus including the above organic electroluminescent device.

The phosphoryl derivatives of the embodiments of the present disclosure are further described below in connection with preparation methods and experimental data.

### Synthesis Example 1

A synthetic route of the phosphoryl derivative represented by formula (1) is as follows:

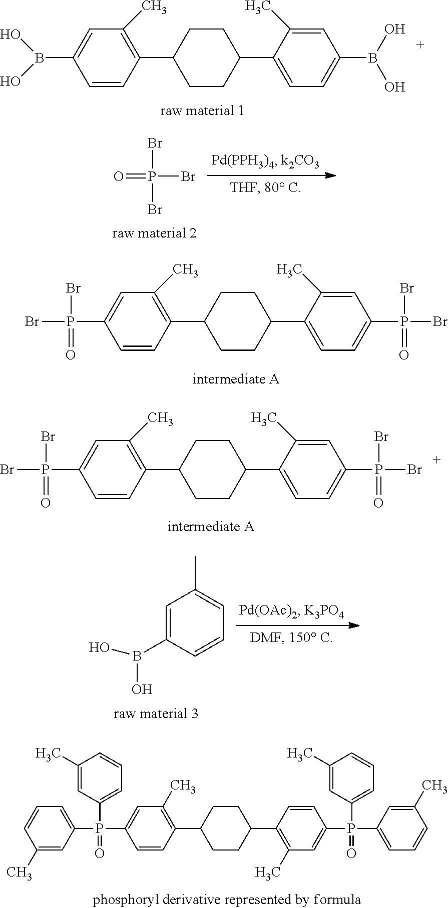

1) In a 500 mL reaction bottle, nitrogen was introduced, 0.3 mol of the raw material 1, 0.3 mol of the raw material 2, THF, 2-naphthalene boric acid and 0.003 mol of tetra(triphenylphosphine) palladium were each added and stirred, and then K₂CO₃ aqueous solution was added, heated to 80° C., refluxed for 12 hours, sampled and spotted, and the reaction was completed. Natural cooling, extraction with dichloromethane, and stratification were performed, and extraction liquid was dried with anhydrous sodium sulfate and filtered, and filtrate was subjected to rotary evaporation, and purification through silica gel column, to obtain the intermediate A.
2) In a 500 mL three-necked bottle, nitrogen was introduced, 0.02 mol of the intermediate A, 0.02 mol of the raw material 3, DMF and 0.002 mol of palladium acetate were added and stirred, then 0.01 mol of K₃PO₄ aqueous solution was added, heated to 150° C., refluxed for 24 hours, sampled and spotted, and the reaction was completed. Natural cooling, extraction with dichloromethane, and stratification were performed, and extraction liquid was dried with anhydrous sodium sulfate and filtered, and filtrate was subjected to rotary evaporation, and purification through silica gel column, to obtain the phosphoryl derivative represented by formula (1).

Mass spectrometry m/z: 720.87, element content (%): C₄₈H₅₀O₂P₂, C, 79.98; H, 6.99; O, 4.44; P, 8.59.

1H NMR: 7.67 (12H), 7.5-7.47 (6H), 7.33 (4H), 2.72 (2H), 2.36 (12H), 2.29 (6H), 1.85 (4H), 1.605 (4H).

### Synthesis Example 2

A synthetic route of the phosphoryl derivative represented by formula (4) is as follows:

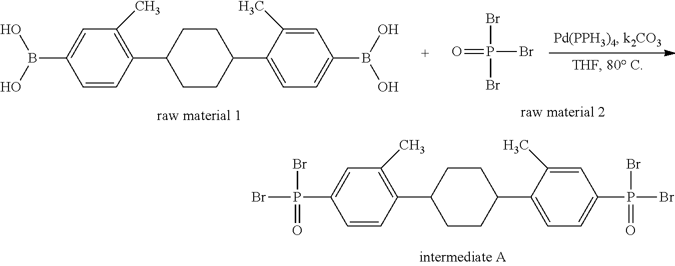 [SMILES: Cc1cc(B(O)O)ccc1C1CCC(c2ccc(B(O)O)cc2C)CC1 ; O=P(Br)(Br)Br ; Cc1cc(P(=O)(Br)Br)ccc1C1CCC(c2ccc(P(=O)(Br)Br)cc2C)CC1]

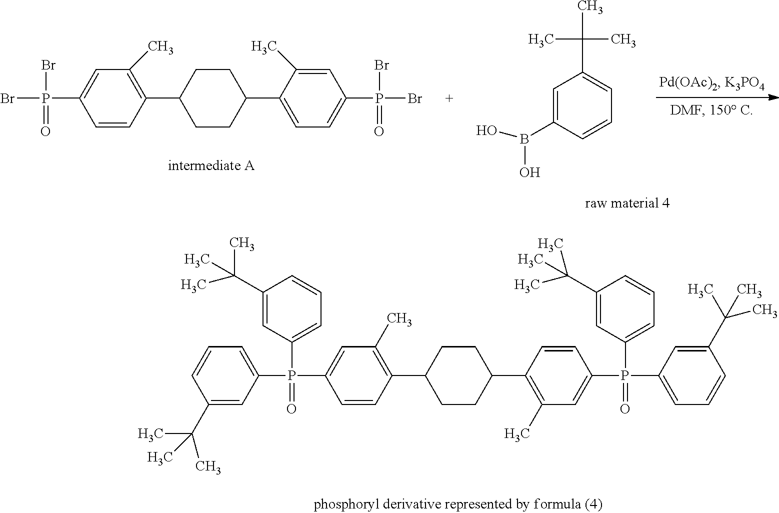 [SMILES: Cc1cc(P(=O)(Br)Br)ccc1C1CCC(c2ccc(P(=O)(Br)Br)cc2C)CC1 ; CC(C)(C)c1cccc(B(O)O)c1 ; Cc1cc(P(=O)(c2cccc(C(C)(C)C)c2)c2cccc(C(C)(C)C)c2)ccc1C1CCC(c2ccc(P(=O)(c3cccc(C(C)(C)C)c3)c3cccc(C(C)(C)C)c3)cc2C)CC1]

The preparation of the phosphoryl derivative represented by formula (4) differs from the preparation of the phosphoryl derivative represented by formula (1) in Example 1 in that the raw material 3 is replaced by the raw material 4 to obtain the phosphoryl derivative represented by formula (4).

Mass spectrometry m/z: 889.2, element content (%): C₆₀H₇₄O₂P₂, C, 81.05; H, 8.39; O, 3.6; P, 6.97.

1H NMR: 7.82 (3H), 7.67-7.66 (7H), 7.57-7.47 (8H), 3.3 (1H), 2.72 (2H), 2.29 (6H), 2.05 (3H), 1.85 (4H), 1.605 (4H), 1.35 (9H), 1.32 (27H).

### Synthesis Example 3

A synthetic route of the phosphoryl derivative represented by formula (5) is as follows:

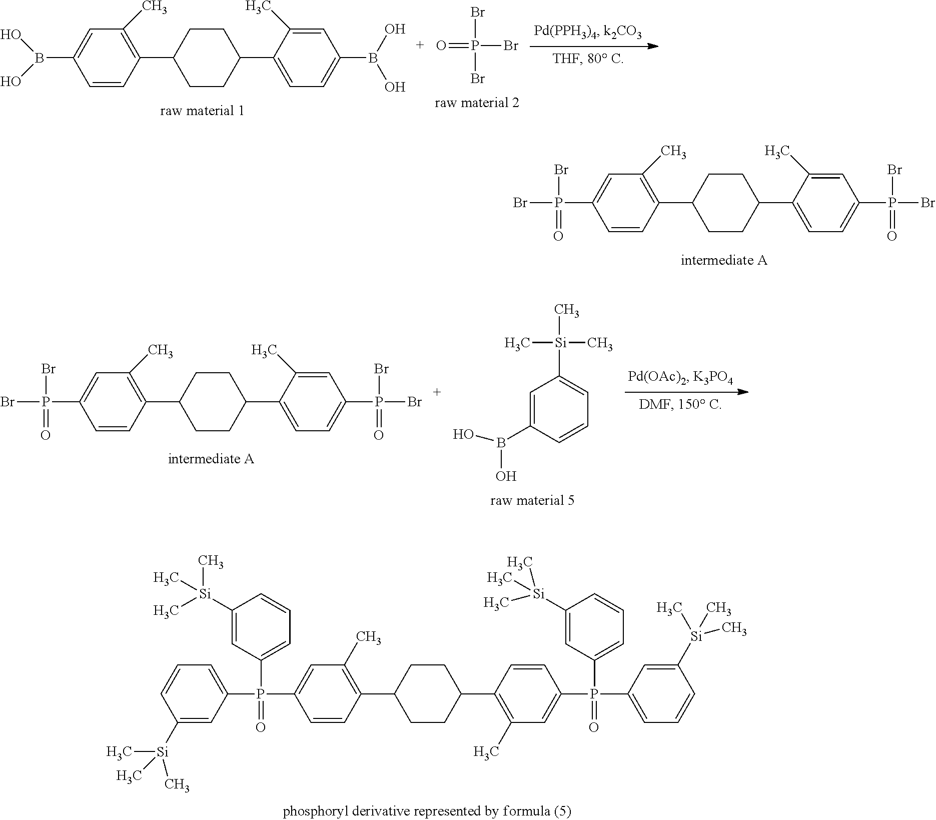

The preparation of the phosphoryl derivative represented by formula (5) differs from the preparation of the phosphoryl derivative represented by formula (1) in Example 1 in that the raw material 3 is replaced by the raw material 5 to obtain the phosphoryl derivative represented by formula (5).

Mass spectrometry m/z: 953.49, element content (%): C₅₆H₇₄O₂P₂Si₄, C, 70.54; H, 7.82; O, 3.36; P, 6.50; Si, 11.78.

1H NMR: 8.01 (4H), 7.75-7.65 (12H), 7.53-7.47 (6H), 2.72 (2H), 2.29 (6H), 1.85 (4H), 1.605 (4H), 0.25 (36H).

### Synthesis Example 4

A synthetic route of the phosphoryl derivative represented by formula (12) is as follows:

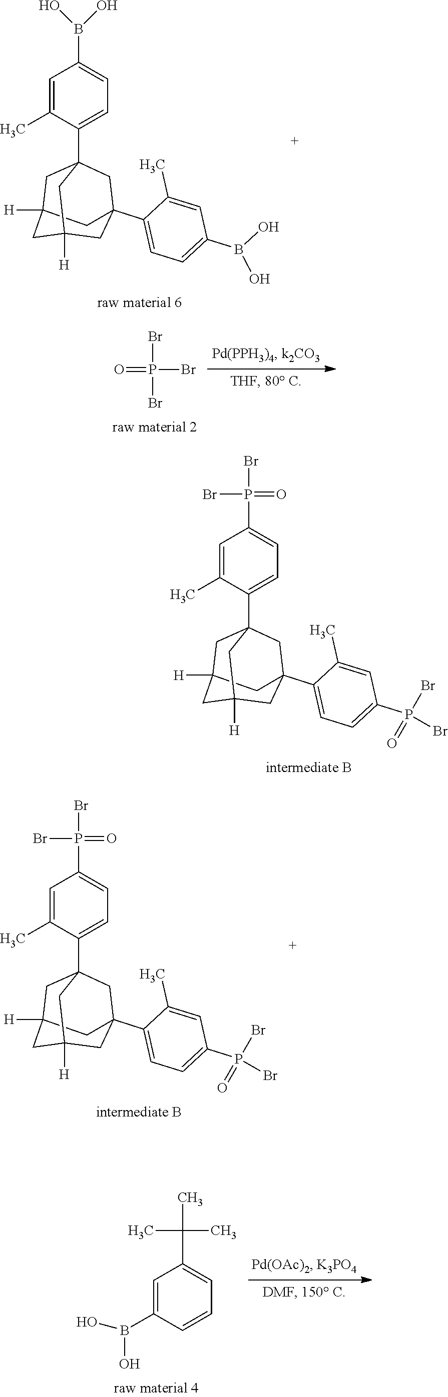 [SMILES: Cc1cc(B(O)O)ccc1C12CC3CC(C1)CC(c1ccc(B(O)O)cc1C)(C3)C2 ; O=P(Br)(Br)Br ; Cc1cc(P(=O)(Br)Br)ccc1C12CC3CC(C1)CC(c1ccc(P(=O)(Br)Br)cc1C)(C3)C2 ; Cc1cc(P(=O)(Br)Br)ccc1C12CC3CC(C1)CC(c1ccc(P(=O)(Br)Br)cc1C)(C3)C2 ; CC(C)(C)c1cccc(B(O)O)c1]

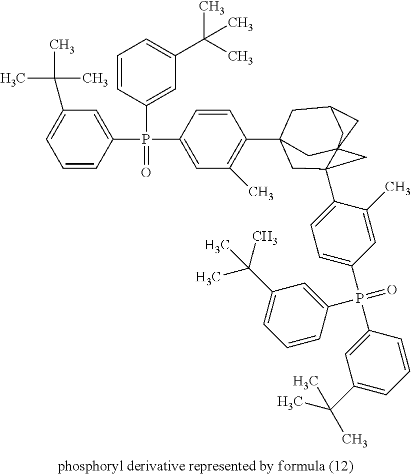

The preparation of the phosphoryl derivative represented by formula (12) differs from the preparation of the phosphoryl derivative represented by formula (1) in Example 1 in that the raw material 1 is replaced by the raw material 6 and the raw material 3 is replaced by the raw material 4 to obtain the phosphoryl derivative represented by formula (12).

Mass spectrometry m/z: 941.27, element content (%): C₆₄H₇₈O₂P₂, C, 81.67; H, 8.35; O, 3.40; P, 6.58.

1H NMR: 7.82 (4H), 7.66 (4H), 7.59-7.57 (8H), 7.47-7.46 (6H), 2.29-2.02 (7H), 1.85 (2H), 1.775-1.485 (6H), 1.47-1.41 (4H), 1.32 (36H), 1.01 (1H).

### Synthesis Example 5

A synthetic route of the phosphoryl derivative represented by formula (14) is as follows:

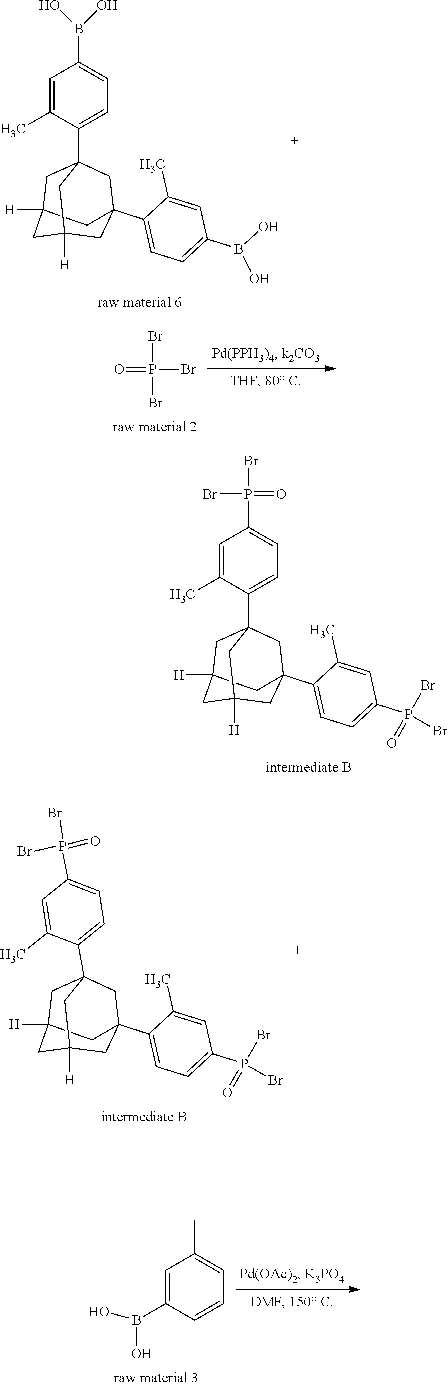

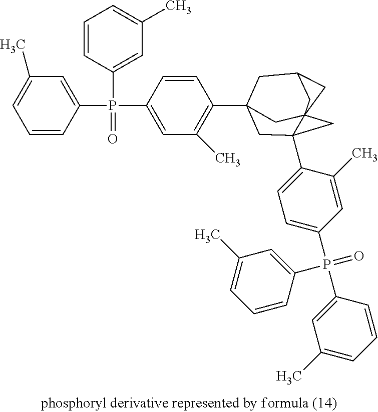

The preparation of the phosphoryl derivative represented by formula (14) differs from the preparation of the phosphoryl derivative represented by formula (1) in Example 1 in that the raw material 1 is replaced by the raw material 6 to obtain the phosphoryl derivative represented by formula (14).

Mass spectrometry m/z: 772.95, element content (%): C₅₂H₅₄O₂P₂, C, 80.80; H, 7.04; O, 4.14; P, 8.01.

1H NMR: 7.67 (8H), 7.59-7.50 (8H), 7.46-7.33 (6H), 2.36 (12H), 2.29-2.02 (7H), 1.85 (2H), 1.775-1.485 (6H), 1.47-1.41 (4H), 1.07 (1H).

### Synthesis Example 6

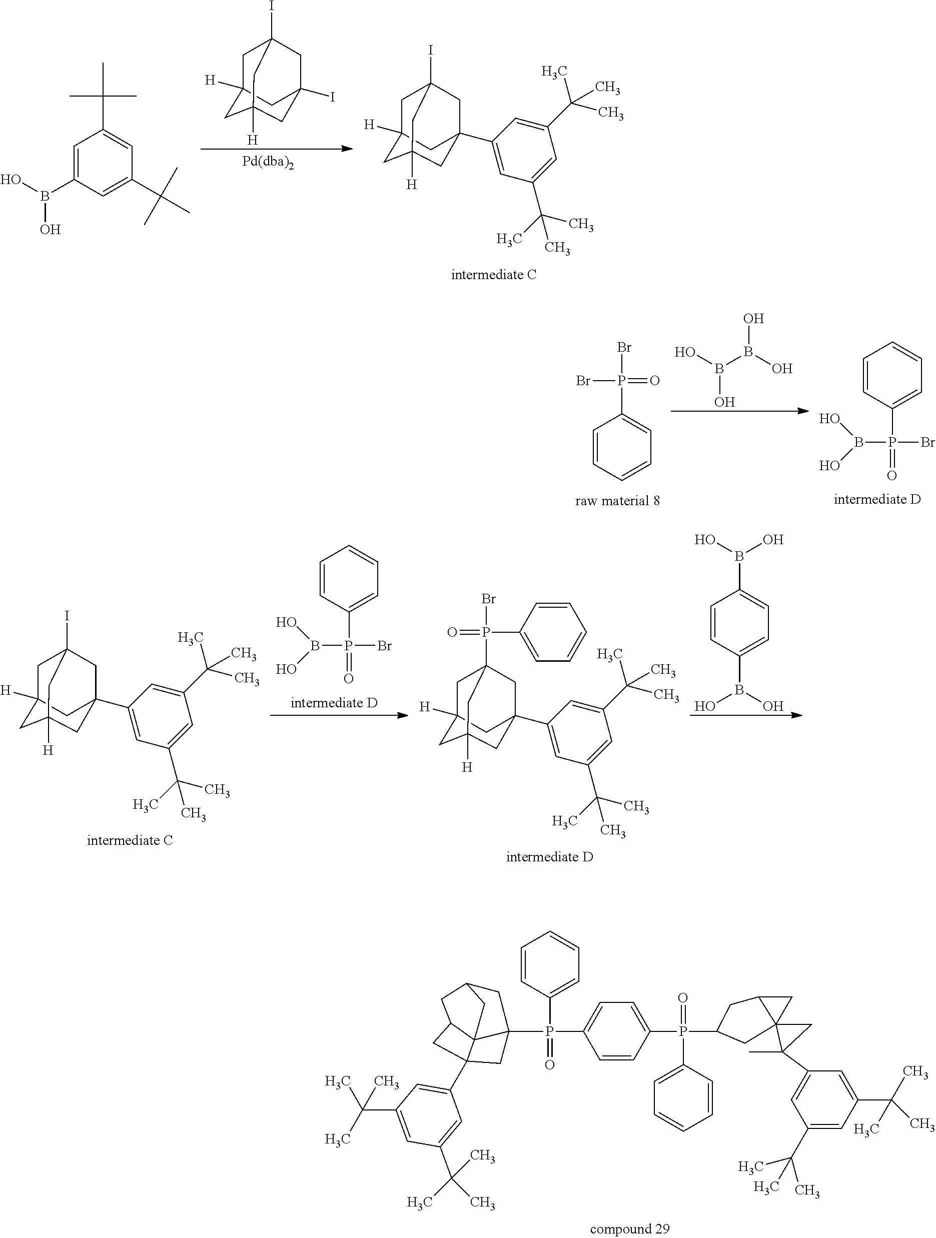

1) In a 500 mL reaction bottle, nitrogen was introduced, toluene solvent, 0.3 mol of the raw material 7, 0.3 mol of iodoadamantane, and 0.003 mol of Pd (dba)₂ were added and stirred, reacted at room temperature, refluxed for 12 hours, sampled and spotted, and the reaction was completed. Extraction with dichloromethane and stratification were performed, and extraction liquid was dried with anhydrous sodium sulfate and filtered, to obtain the intermediate C.
2) In a 500 mL reaction bottle, methanol solvent, 0.2 mol of the raw material 8, and 0.2 mol of tetrahydroxydiboron were added and stirred, reacted at 15° C. for 24 h, and irradiated with UV lamp (254 nm). The resultant was sampled and spotted, and the reaction was completed. Filtration was performed, and the intermediate D was obtained.
3) In a 500 mL three-necked bottle, nitrogen was introduced, 0.02 mol of the intermediate C, 0.02 mol of the intermediate D, toluene solvent and 0.002 mol of Pd (dba)₂ were added and stirred, heated to 80° C., refluxed for 24 hours, sampled and spotted, and the reaction was completed. Natural cooling and filtration were performed, and the intermediate E was obtained.
4) According to reaction 2), 0.1 mol of the intermediate E and 0.1 mol of p-di(dihydroxyboron)benzene were reacted, and the compound 29 was obtained.

Mass spectrometry m/z: 971.34, element content (%): C₆₆H₈₄O₂P₂, C, 81.61; H, 8.72; O, 3.29; P, 6.38.

1H NMR: 7.97 (4H), 7.8-7.77 (4H), 7.51-7.35 (7H), 7.25 (3H), 7.18 (2H), 2.9 (1H), 1.96-1.75 (6H), 1.62-1.41 (10H), 1.32-1.31 (16H), 1.12 (1H).

### Performance Test of Phosphoryl Derivative Materials:

Based on the preparation methods of Synthesis Examples 1 to 6, the embodiments of the present disclosure prepared phosphoryl derivatives represented by formulas (1) to (41).

A phosphoryl derivative film was evaporated on a silicon wafer, and a thickness of the phosphoryl derivative film was 50 nm; a refractive index of the phosphoryl derivative film was measured by an ellipsometer, and a scanning range of the ellipsometer was 245 nm to 1000 nm. The refractive index test results of the phosphoryl derivative films were shown in Table 1.

A glass transition temperature (Tg) determines the thermal stability of the material in the evaporation. The higher the Tg is, the better the thermal stability of the material is. DSC differential scanning calorimeter was used to measure the glass transition temperature of the phosphoryl derivative with nitrogen measuring atmosphere, heating rate of 10° C./min and temperature range of 50° C. to 300° C. The measured glass transition temperature results were shown in Table 2.

Herein, a compound used in Comparative Example 1 is represented by formula (CP1):

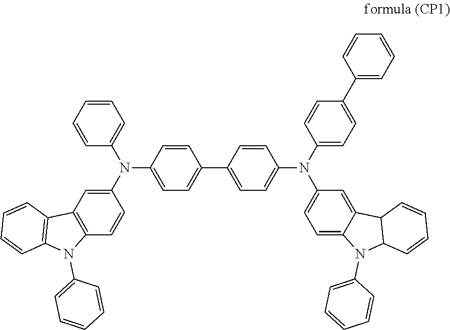 [SMILES: C1=CC2c3cc(N(c4ccc(-c5ccccc5)cc4)c4ccc(-c5ccc(N(c6ccccc6)c6ccc7c(c6)c6ccccc6n7-c6ccccc6)cc5)cc4)ccc3N(c3ccccc3)C2C=C1]

TABLE 1
Refractive index of the phosphoryl derivative film

| | | Refractive index n at | | |
|---|---|---|---|---|
| | | different wavelengths | | |
| Test number | Test film | 460 nm | 530 nm | 620 nm |
| Comparative | compound represented | 1.93 | 1.86 | 1.83 |
| Example 1 | by formula (CP1) | | | |
| Example 1 | phosphoryl derivative | 1.601 | 1.598 | 1.585 |
| | represented by formula (1) | | | |
| Example 2 | phosphoryl derivative | 1.59 | 1.580 | 1.566 |
| | represented by formula (2) | | | |
| Example 3 | phosphoryl derivative | 1.60 | 1.585 | 1.571 |
| | represented by formula (3) | | | |
| Example 4 | phosphoryl derivative | 1.571 | 1.556 | 1.544 |
| | represented by formula (4) | | | |
| Example 5 | phosphoryl derivative | 1.582 | 1.566 | 1.550 |
| | represented by formula (5) | | | |
| Example 6 | phosphoryl derivative | 1.560 | 1.545 | 1.535 |
| | represented by formula (12) | | | |
| Example 7 | phosphoryl derivative | 1.569 | 1.554 | 1.546 |
| | represented by formula (14) | | | |
| Example 8 | phosphoryl derivative | 1.550 | 1.535 | 1.525 |
| | represented by formula (17) | | | |
| Example 9 | phosphoryl derivative | 1.54 | 1.530 | 1.519 |
| | represented by formula (21) | | | |
| Example 10 | phosphoryl derivative | 1.549 | 1.538 | 1.526 |
| | represented by formula (22) | | | |

Compared with the refractive index of the compound material of Comparative Example 1 at different wavelengths, the refractive indices of the phosphoryl derivative materials of the embodiments of the present disclosure are lower than that of the compound material of Comparative Example 1, and the phosphoryl derivative materials can replace the inorganic LiF, for example, to cover on the conventional CPL with higher refractive index in flexible encapsulation display device, which is beneficial to the optical coupling output of the device, improves the efficiency of the device, and at the same time avoids disadvantages of using the inorganic low refractive index materials to cover.

TABLE 2
Glass transition temperatures (Tg) of the phosphoryl derivatives

| | | Tg |
|---|---|---|
| Test number | Test material | ° C. |
| Comparative | compound represented by formula (CP1) | 130 |
| Example 1 | | |
| Example 1 | phosphoryl derivative represented by formula (1) | 130 |
| Example 2 | phosphoryl derivative represented by formula (2) | 131 |
| Example 3 | phosphoryl derivative represented by formula (3) | 134 |
| Example 4 | phosphoryl derivative represented by formula (4) | 135 |
| Example 5 | phosphoryl derivative represented by formula (5) | 138 |
| Example 6 | phosphoryl derivative represented by formula (12) | 140 |
| Example 7 | phosphoryl derivative represented by formula (14) | 143 |
| Example 8 | phosphoryl derivative represented by formula (17) | 142 |
| Example 9 | phosphoryl derivative represented by formula (21) | 132 |
| Example 10 | phosphoryl derivative represented by formula (22) | 133 |

Compared with the glass transition temperature of the compound material of Comparative Example 1, the glass transition temperatures of the phosphoryl derivatives of the embodiments of the present disclosure are higher, and thus, the stability of the phosphoryl derivatives of the embodiments of the present disclosure is higher in the evaporation process, which can meet the temperature requirements of the evaporation process.

Performance Test of Organic Electroluminescent Devices Containing the Phosphoryl derivatives:

A top emission organic electroluminescent device was prepared by vacuum evaporation, and the phosphoryl derivatives of the examples of the present disclosure were tested as the optical coupling effect of CPL. A device structure of the examples of the present disclosure used for the following device performance tests is shown in FIG. 2, including an anode electrode layer 100, a hole injection layer 200, a hole transport layer 300, an electron barrier layer 400, a light emitting layer 500, a hole barrier layer 600, an electron transport layer 700, an electron injection layer 800, a cathode electrode layer 900 and an optical coupling output layer which are sequentially laminated, herein, the optical coupling output layer includes a first optical coupling output layer 1100 and a second optical coupling output layer 1200, and a thin-film encapsulation (TFE) is adopted. Structures, materials and thicknesses of the devices in the examples of the present disclosure were shown in Table 3.

TABLE 3
Structures and thicknesses of the devices

| | Material and thickness | | |
|---|---|---|---|
| Structure | Blue light | Green light | Red light |
| anode electrode | ITO | ITO | ITO |
| layer/Anode | | | |
| hole injection | m- | m- | m- |
| layer/HIL | MTDATA:F4TCNQ | MTDATA:F4TCNQ | MTDATA:F4TCNQ |
| | 3% 10 nm | 3% 10 nm | 3% 10 nm |
| hole transport | m-MTDATA | m-MTDATA | m-MTDATA |
| layer/HTL | 100 nm | 100 nm | 100 nm |
| electron barrier | CBP 10 nm | CBP 45 nm | CBP 75 nm |
| layer/EBL | | | |
| light emitting | BH:BD 5% 20 nm | GH:GD 10% 40 nm | RH:RD 3% 45 nm |
| layer/EML | | | |
| hole barrier | TPBi 5 nm | TPBi 5 nm | TPBi 5 nm |
| layer/HBL | | | |
| electron transport | BCP:Liq 1:1 | BCP:Liq 1:1 | BCP:Liq 1:1 |
| layer/ETL | 30 nm. | 30 nm | 30 nm |
| electron injection | Yb 1 nm | Yb 1 nm | Yb 1 nm |
| layer/EIL | | | |
| cathode electrode | Mg: Ag 13 nm | Mg: Ag 13 nm | Mg: Ag 13 nm |
| layer/Cathode | | | |
| first optical | CP2 80 nm | CP2 80 nm | CP2 80 nm |
| coupling output | | | |
| layer/CPL1 | | | |
| second optical | CPL 60 nm | CPL 60 nm | CPL 60 nm |
| coupling output | | | |
| layer/CPL2 | | | |

Materials for the second optical coupling output layer in Table 3 were selected from the compound represented by formula (CP1) and the phosphoryl derivatives represented by formula (1) to formula (41) in the examples of the present disclosure, and structural formulas of the materials employed in Table 3 were as follows:

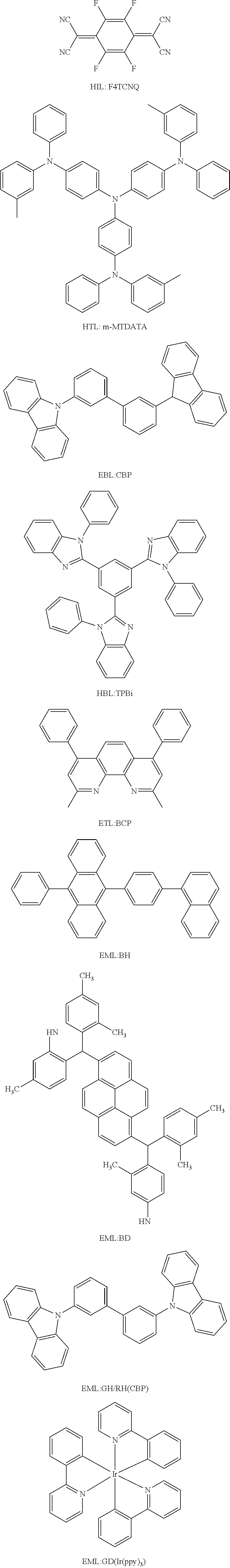

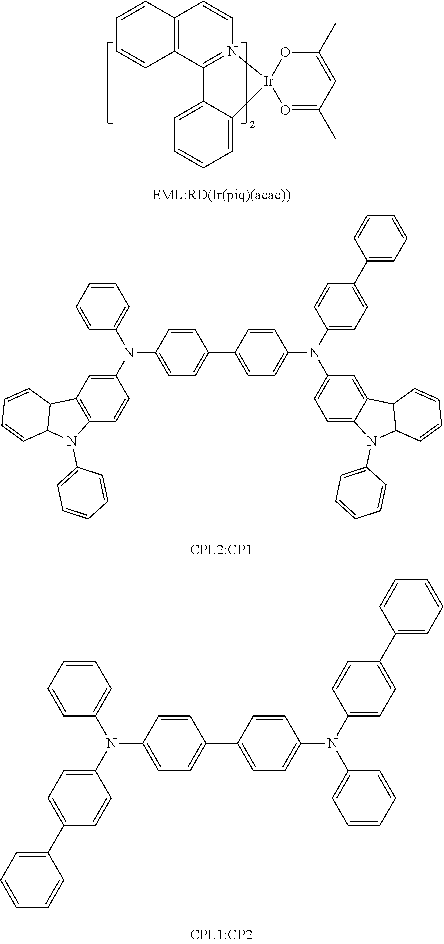

According to the structures, materials and thickness data of the top light emitting organic electroluminescent devices shown in Table 3, the corresponding organic electroluminescent devices were prepared from the compound CP1 of Comparative Example 1 and the phosphoryl derivatives of Examples 1 to 10 of the present disclosure as the second optical coupling output layer/CPL2, respectively, and the measured performance detection results of blue light organic electroluminescent devices were shown in Table 4.

TABLE 4
Performance detection results of the blue
light organic electroluminescent device

| | | | | Life (LT95 |
|---|---|---|---|---|
| Test number | CPL2 | Voltage | EQE | @ 1000 nit) |
| Comparative | compound represented | 100% | 100% | 100% |
| Example 1 | by formula (CP1) | | | |
| Example 1 | phosphoryl derivative | 99% | 101% | 101% |
| | represented by formula (1) | | | |
| Example 2 | phosphoryl derivative | 100% | 104% | 102% |
| | represented by formula (2) | | | |
| Example 3 | phosphoryl derivative | 98% | 103% | 104% |
| | represented by formula (3) | | | |
| Example 4 | phosphoryl derivative | 98% | 105% | 104% |
| | represented by formula (4) | | | |
| Example 5 | phosphoryl derivative | 99% | 104% | 106% |
| | represented by formula (5) | | | |
| Example 6 | phosphoryl derivative | 100% | 105% | 108% |
| | represented by formula (12) | | | |
| Example 7 | phosphoryl derivative | 97% | 104% | 108% |
| | represented by formula (14) | | | |
| Example 8 | phosphoryl derivative | 98% | 107% | 107% |
| | represented by formula (17) | | | |
| Example 9 | phosphoryl derivative | 100% | 108% | 102% |
| | represented by formula (21) | | | |
| Example 10 | phosphoryl derivative | 99% | 107% | 103% |
| | represented by formula (22) | | | |

As can be seen from the test results in Table 4, compared with the blue light organic electroluminescent device prepared using CP1 material as the second optical coupling output layer of Comparative Example 1, the blue light organic electroluminescent devices prepared using the phosphoryl derivatives of the examples of the present disclosure as the second optical coupling output layer have higher light extraction efficiency, better stability, and improved efficiency and life. Furthermore, the examples of the present disclosure further uses the above comparative experimental method to detect performances of the red light organic electroluminescent devices and the green light organic electroluminescent devices, and the obtained detection results are similar to those of the blue light organic electroluminescent devices.

It can be known from the above experimental data of the examples of the present disclosure that the optical coupling output layers, which are formed by using the phosphoryl derivatives provided by the examples of the present disclosure as the low refractive index materials covering the high refractive index materials, have characteristics of higher effect, better thermal stability and longer life.

In embodiments of the present disclosure, the first feature being “above” or “below” the second feature may include direct contact of the first and second features, or may include contact of the first and second features not directly but through additional features between them, unless otherwise expressly specified and defined. Moreover, the first feature being “over”, “upper” and “on” the second feature may mean that the first feature is directly above or obliquely above the second feature, or simply mean that a level of the first feature is greater than that of the second feature. The first feature being “below”, “beneath” and “under” the second feature may mean that the first feature is directly below or obliquely below the second feature, or simply mean that a level of the first feature is less than that of the second feature.

In the description of the present disclosure, it should be understood that, orientation or position relationships indicated by terms “center”, “longitudinal”, “transverse”, “length”, “width”, “thickness”, “upper”, “lower”, “front”, “back”, “left”, “right”, “vertical”, “horizontal”, “top”, “bottom”, “inside”, “outside”, “clockwise”, “counterclockwise”, and the like are based on the orientation or position relationships shown in the drawings, and are only for the convenience of description of the present disclosure and simplification of the description, but are not intended to indicate or imply that the mentioned device or element must have a specific orientation, or be constructed and operated in a particular orientation, and therefore they should not be construed as limitations on the present disclosure.

It should be noted that all directivity indications in the embodiment of the present disclosure are only used to explain the relative position relationship and motion situation among the components under a specific attitude, and if the specific attitude is changed, the directivity indications are changed accordingly.

In the present disclosure, unless otherwise clearly specified and defined, terms “linked”, “fixed” and other terms should be broadly understood. For example, the term “fixed” may be linked fixedly or linked detachably, or integrated; or to be mechanically linked or electrically linked; or to be directly linked, or be indirectly linked through an intermediary, or be internally linked between two elements or be interacted between two elements, unless otherwise clearly specified. For those of ordinary skill in the art, specific meanings of the abovementioned terms in the embodiments of the disclosure can be understood according to a specific condition.

In addition, descriptions such as those relating to “first”, “second” and the like in embodiments of the present disclosure are for descriptive purposes only and cannot be construed as indicating or implying their relative importance or implying the number of technical features indicated. Therefore, features defined by “first” and “second” may explicitly or implicitly indicate inclusion of one or more such features. In the description of the present disclosure, “a plurality of” means two or more than two, unless defined otherwise explicitly.

In descriptions of this specification, descriptions of reference terms “an embodiment,” “some embodiments,” “an example,” “a specific example,” or “some examples”, etc., mean that a particular feature, a structure, a material, or a characteristic described in conjunction with the embodiment or the example is included in at least one embodiment or example of the present disclosure. In this specification, a schematic expression of the above terms does not necessarily refer to a same embodiment or example. Moreover, the specific features, structures, materials, or characteristics described may be combined in any one or more embodiments or examples in a proper way. Further, those skilled in the art may join and combine different embodiments or examples described in this specification.

In addition, the technical solutions among the various embodiments may be combined with each other, but must be on the basis that the person of ordinary skill in the art can realize it. When the combination of technical solutions conflicts or cannot be realized, it should be considered that the combination of technical solutions does not exist and is not within the scope of protection claimed by the present application.

Although implementation modes of the present disclosure have been illustrated and described, those of ordinary skill in the art may understand that multiple changes, modifications, substitutions, and variations may be made to these implementation modes without departing from principles and purposes of the present disclosure. The scope of the present disclosure is defined by the claims and their equivalents.

1. A phosphoryl derivative, wherein, a phosphoryl group of the phosphoryl derivative is directly linked to two substituted or unsubstituted aryls, and is at least directly linked to a non-conjugated substituent or indirectly linked to the non-conjugated substituent via a bridged group;
the non-conjugated substituent is independently selected from substituted or unsubstituted C3-C10 alkyl, substituted or unsubstituted C3-C10 cycloalkyl, or substituted or unsubstituted adamantyl; and
the bridged group is independently selected from substituted or unsubstituted C6-C60 aryl, substituted or unsubstituted C10-C60 fused aryl, or substituted or unsubstituted C5-C60 5-membered or 6-membered arylheterocyclyl.

2. The phosphoryl derivative according to claim 1, wherein, the phosphoryl derivative comprises two phosphoryl groups, and the two phosphoryl groups are indirectly linked.

3. The phosphoryl derivative according to claim 2, wherein, the two phosphoryl groups are indirectly linked by a substituted or unsubstituted aryl directly linked to the phosphoryl group or by the non-conjugated substituent.

4. The phosphoryl derivative according to claim 2, wherein, the bridged group is a substituted or unsubstituted aryl.

5. The phosphoryl derivative according to claim 1, wherein, any one or more of a substituted aryl directly linked to the phosphoryl group, the non-conjugated substituent and the bridged group is further linked to a sterically hindered substituent independently selected from halogen-substituted alkane, nitro, nitrile group, substituted or unsubstituted C1-C30 alkyl, silyl, substituted or unsubstituted C2-C30 alkenyl, substituted or unsubstituted C1-C30 alkoxy, substituted or unsubstituted C1-C30 thioether group, substituted or unsubstituted C6-C50 aryl, or C2-C50 heteroaryl formed from a substituted or unsubstituted C2-C9 ring structure.

6. The phosphoryl derivative according to claim 1, wherein, the phosphoryl derivative has a structure represented by general formula (I) or general formula (II): 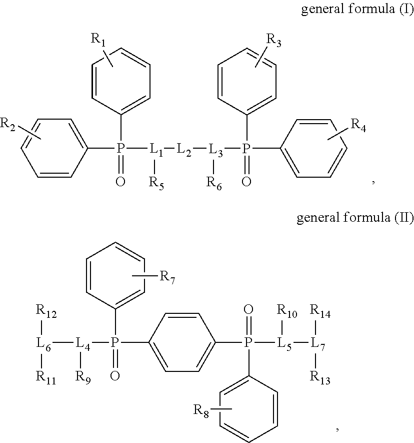
in the general formula (I), L1, L2, and L3 are each independently selected from C6-C60 aryl, C10-C60 fused aryl, C5-C60 5-membered or 6-membered arylheterocyclyl, or the non-conjugated substituent, and at least one of L1, L2, and L3 is the non-conjugated substituent; R1, R2, R3, R4, R5, and R6 are each independently selected from hydrogen, deuterium, halogen, halogen-substituted alkane, nitro, nitrile group, substituted or unsubstituted C1-C30 alkyl, silyl, substituted or unsubstituted C2-C30 alkenyl, substituted or unsubstituted C1-C30 alkoxy, substituted or unsubstituted C1-C30 thioether group, substituted or unsubstituted C6-C50 aryl, or C2-C50 heteroaryl formed from a substituted or unsubstituted C2-C9 ring structure;
in the general formula (II), L4, L5, L6, and L7 are each independently selected from C6-C60 aryl, C10-C60 fused aryl, C5-C60 5-membered or 6-membered arylheterocyclyl, the non-conjugated substituent, and at least one of L4, L5, L6, and L7 is the non-conjugated substituent; R7, R8, R9, R10, R11, R12, R13, and R14 are each independently selected from hydrogen, deuterium, halogen, halogen-substituted alkane, nitro, nitrile group, substituted or unsubstituted C1-C30 alkyl, silyl, substituted or unsubstituted C2-C30 alkenyl, substituted or unsubstituted C1-C30 alkoxy, substituted or unsubstituted C1-C30 thioether group, substituted or unsubstituted C6-C50 aryl, or C2-C50 heteroaryl formed from a substituted or unsubstituted C2-C9 ring structure.

7. The phosphoryl derivative according to claim 6, wherein, the phosphoryl derivative has a structure represented by any one of the following formulas:

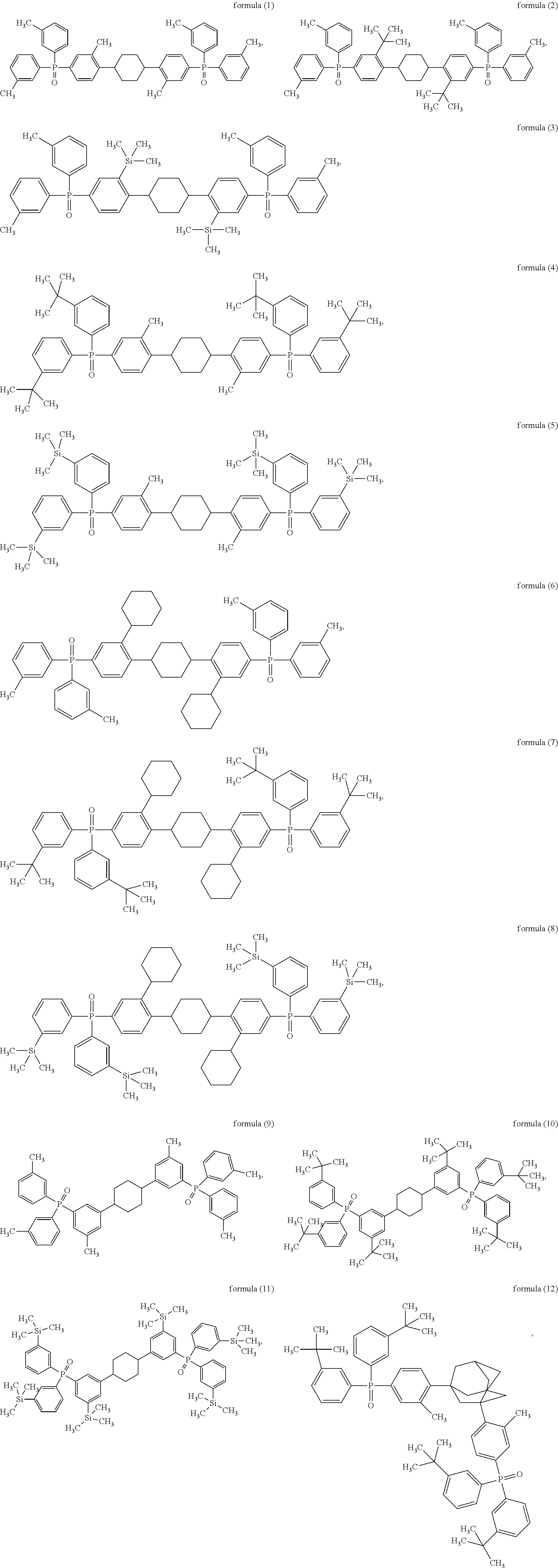

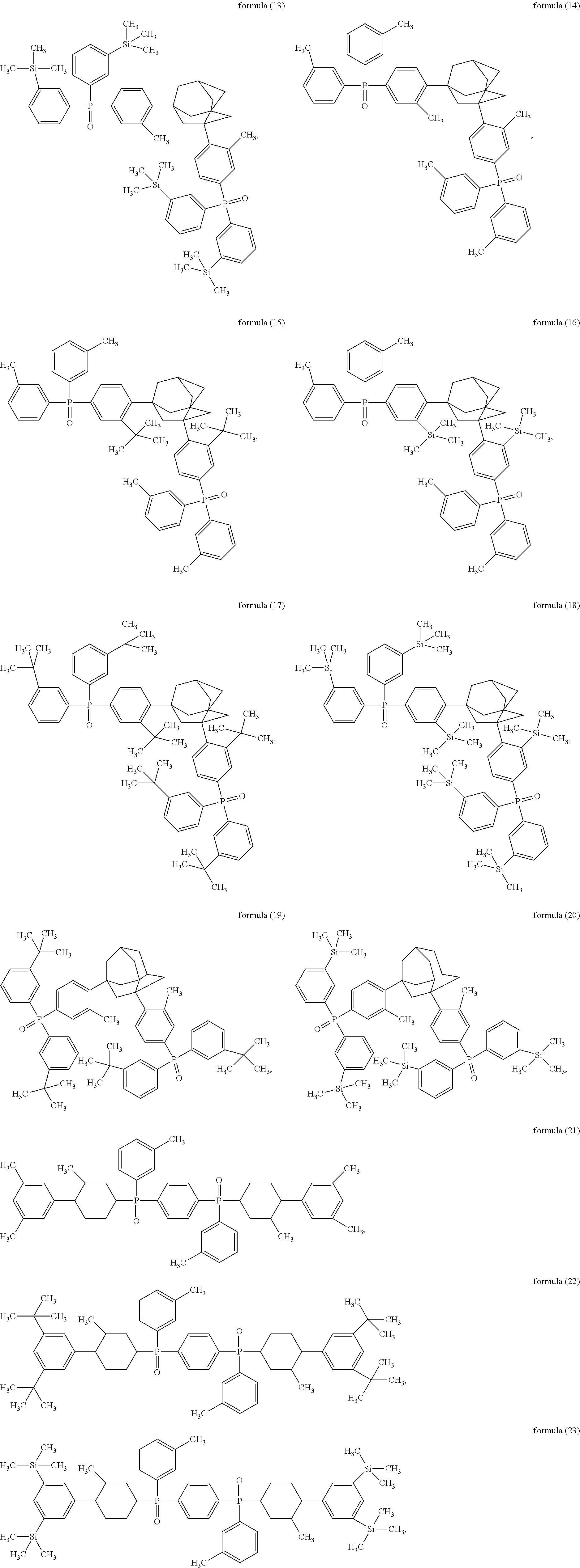

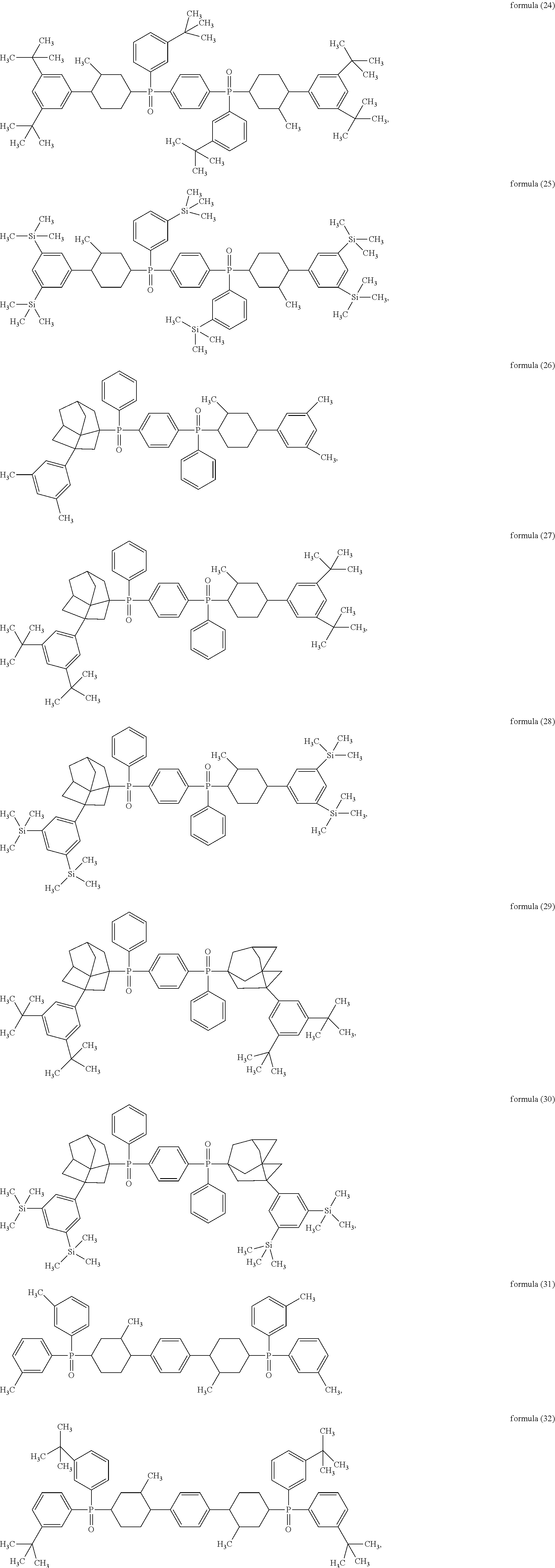

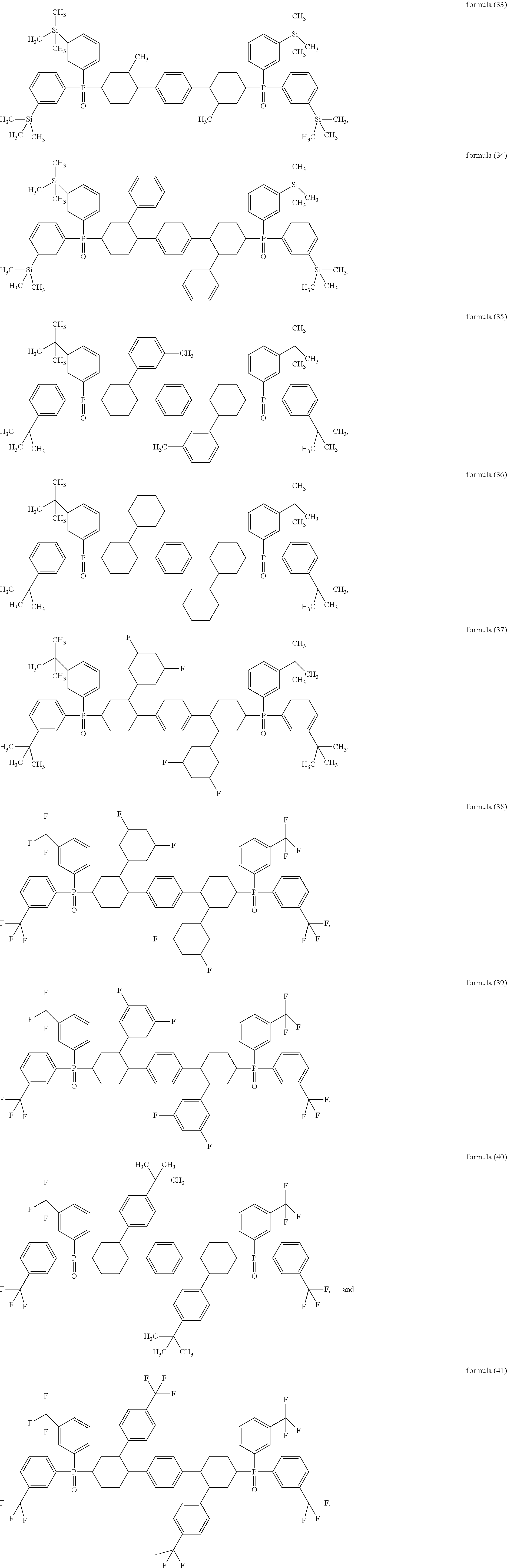

8. Use of the phosphoryl derivative according to claim 1, wherein, the phosphoryl derivative is used for preparing an optical coupling output layer of an organic electroluminescent device.

9. An organic electroluminescent device comprising an anode electrode layer, a hole injection layer, a hole transport layer, a light emitting layer, an electron transport layer, an electron injection layer, a cathode electrode layer, and an optical coupling output layer which are sequentially laminated, wherein the optical coupling output layer comprises the phosphoryl derivative according to claim 1.

10. A display apparatus comprising the organic electroluminescent device according to claim 9.
